(19) United States
(12) Patent Application Publication
(10) Pub. No.: US 2017/0019989 A1
(43) Pub. Date: Jan. 19, 2017

(54) CIRCUIT BOARD AND MANUFACTURING METHOD OF THE SAME

(71) Applicant: SAMSUNG ELECTRO-MECHANICS CO., LTD., Suwon-si (KR)

(72) Inventor: Chang-Bo LEE, Suwon-si (KR)

(73) Assignee: SAMSUNG ELECTRO-MECHANICS CO., LTD., Suwon-si (KR)

(21) Appl. No.: 15/050,850

(22) Filed: Feb. 23, 2016

(30) Foreign Application Priority Data
Jul. 15, 2015 (KR) 10-2015-0100633

(51) Int. Cl. H05K 1/02; H05K 3/00

(52) U.S. Cl. CPC H05K 1/0298; H05K 3/0026

(57) ABSTRACT

A circuit board includes an insulating layer, a first circuit layer that is buried in one surface of the insulating layer, a metal post located on the first circuit layer, and a barrier layer located on a portion of the interface between the first circuit layer and the metal post. Also, a method for manufacturing a circuit board includes forming a barrier layer on at least one surface of the carrier board, forming a circuit layer on the barrier layer, forming an insulating layer into which the circuit layer is buried, eliminating at least a part of the carrier board, eliminating at least a part of the barrier layer to expose a part of the circuit layer, and forming a metal post on the exposed circuit layer. Such a circuit board and method allows for a board with thinner thickness and good electrical performance.

### CROSS REFERENCE TO RELATED APPLICATION(S)

This application claims the benefit under 35 USC 119(a) of Korean Patent Application No. 10-2015-0100633 filed on Jul. 15, 2015 in the Korean Intellectual Property Office, the entire disclosure of which is incorporated herein by reference for all purposes.

### BACKGROUND

1. Field

The following description relates to a circuit board. The following description also relates to a method for manufacturing such a circuit board.

2. Description of Related Art

In current circuit board technologies, finer patterning, thinner sizing, and high functioning have been in demand. Finer patterning denotes that fine line width, pad spacing, alignment strengthening and the like are continuously required according to the semiconductor finer patterning trends. Thinner sizing denotes that thinner thickness of a circuit board is continuously required according to slimming trends for electronic devices. High functioning denotes that passive components and/or active components are embedded in a circuit board and perform multiple functions, consolidating functions that otherwise would be performed by separate components.

Circuit boards with various structures including coreless boards have been provided in order to meet the above-mentioned requirements and goals. A coreless board has a thin thickness as well as similarly advantageous electrical performance characteristics and further allows implementation of finer patterning for circuits.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a circuit board that is able to eliminate recess problems and a method for manufacturing such a circuit board are provided because the recess problems are caused by a circuit layer being exposed through a cavity in a process for manufacturing a circuit board when a coreless board having such a cavity is used.

Hence, the recess problems are eliminated or prevented by forming a barrier layer that covers the circuit layer exposed through the cavity.

In one general aspect, a circuit board includes an insulating layer, a first circuit layer that is buried in one surface of the insulating layer, a metal post located on the first circuit layer, and a barrier layer located on a portion of an interface between the first circuit layer and the metal post.

The barrier layer may be located along a circumference of the metal post on a lower part of the metal post and the metal post may be connected to the first circuit layer at a center of the metal post.

The circuit board may further comprise a solder resist located to expose a part of the first circuit layer and the metal post.

The barrier layer may extend onto a lower part of the solder resist.

The metal post and the solder resist may be arranged at an edge of the circuit board so to define a cavity at a center of the circuit board.

A width of the metal post may be equal to or greater than a width of the first circuit layer.

The barrier layer may be formed of an organic material.

The barrier layer may be formed of a photosensitive material.

The circuit board may have a coreless structure.

In another general aspect, a circuit board includes an insulating layer, a first circuit layer that is buried in one surface of the insulating layer and includes a first circuit pattern that is formed at a center of the first circuit layer and a second circuit pattern formed at an edge of the first circuit pattern, a metal post formed on the second circuit pattern, and a barrier layer formed on a portion of the interface between the second circuit pattern and the metal post.

In another general aspect, a method for manufacturing a circuit board includes preparing a carrier board, forming a barrier layer on a surface of the carrier board, forming a circuit layer on the barrier layer, forming an insulating layer into which the circuit layer is buried, eliminating at least a part of the carrier board, eliminating at least a part of the barrier layer to expose a part of the circuit layer, and forming a metal post on the exposed circuit layer.

The metal post may be formed to extend into the barrier layer and the barrier layer is thus formed on a portion of the interface between the metal post and the circuit layer.

The at least a part of the barrier layer may be eliminated using a laser.

The method may further include eliminating the exposed barrier layer after the forming the metal post.

The metal layer of the carrier board may be made to remain on the barrier layer after the eliminating at least a part of the carrier board, and the metal post may be eliminated during the eliminating the at least a part of the barrier layer.

The barrier layer may be formed of a photosensitive material.

The method may further include patterning the barrier layer before the forming of the circuit layer.

Other features and aspects will be apparent from the following detailed description, the drawings, and the claims.

### BRIEF DESCRIPTION OF THE DRAWINGS

FIG. 1 is a diagram illustrating an electronic device in which an example of a circuit board is applied.

FIG. 2 and FIG. 3 are diagrams illustrating an example of a circuit board.

FIGS. 4A to 4C are diagrams illustrating portions of an example of a circuit board.

FIG. 5 is a flowchart illustrating an example of a method for manufacturing a circuit board.

FIG. 6A to FIG. 6J are diagrams illustrating steps of an example of a method for manufacturing a circuit board.

FIG. 7 is a diagram illustrating a part of a method for manufacturing a circuit board.

FIG. 8A to FIG. 8D are diagrams illustrating steps of an example of a method for manufacturing a circuit board.

FIG. 9 is a diagram illustrating an example of a semiconductor package including a circuit board.

Throughout the drawings and the detailed description, unless otherwise described or provided, the same drawing reference numerals refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

It is to be understood that, although the terms “first,” “second,” “third,” “fourth” etc. are used herein to describe various elements, these elements are not intended to be limited by these terms. These terms are only used to distinguish one element from another. For example, a first element could potentially be termed a second element, and, similarly, a second element could potentially be termed a first element, without departing from the scope of the present disclosure. Similarly, when it is described that a method includes series of steps, a sequence of the steps is not a sequence in which the steps should be performed in the sequence, an arbitrary technical step is optionally omitted and/or another arbitrary step, which is not disclosed herein, is optionally added to the method.

It is to be understood that when terms “left,” “right,” “front,” “rear,” “on,” “under,” “over,” “beneath” or the like are used, the terms are merely used for the purpose of description, not describing unchangeable relative positions. For example, the terms used herein are potentially exchangeable to be operated in different directions than shown and described herein under an appropriate environment. It is to be understood that when an element is referred to as being “connected” or “coupled” to another element, the element is possibly directly connected or coupled to the other element or intervening elements are optionally present. In contrast, when an element is referred to as being “directly connected” or “directly coupled” to another element, there are no intervening elements present.

Hereinafter, certain examples of the present disclosure are described in further detail with reference to the accompanying drawings.

Circuit boards according to some examples are applied in various electronic devices, for example, a mobile phone, a personal digital assistant, a digital video camera, a digital still camera, a network system, a computer, a monitor, a television, a video game, a smart watch, and other appropriate various electronic devices that use circuit boards as part of their operation.

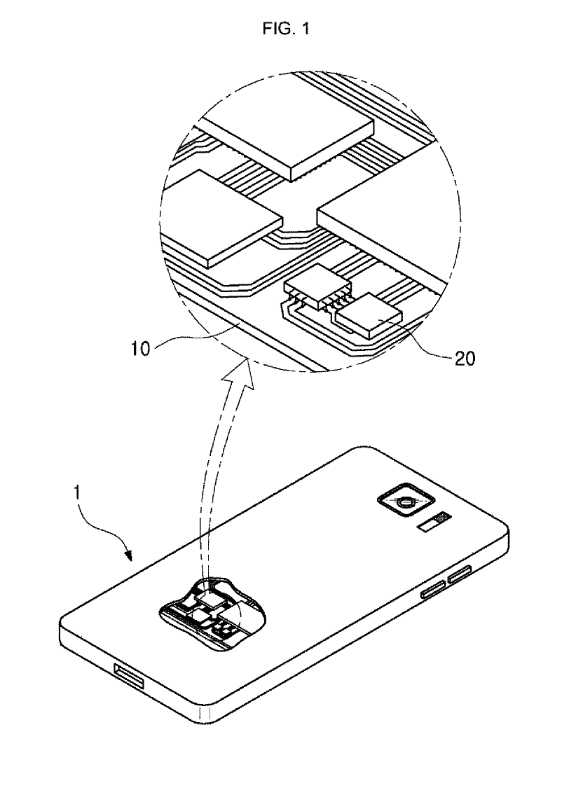

FIG. 1 is a diagram illustrating an electronic device in which an example of a circuit board is applied.

Referring to the example of FIG. 1, a circuit board according to an example is used as a main circuit board 10 to install or embed various electronic components 20 in an electronic device 1. The circuit board is also used as a base board, not shown, of the electronic components 20 such as a semiconductor package that has a smaller size than the circuit board. Furthermore, such a circuit board is possibly applied in various forms to other electronic devices in addition to mobile devices.

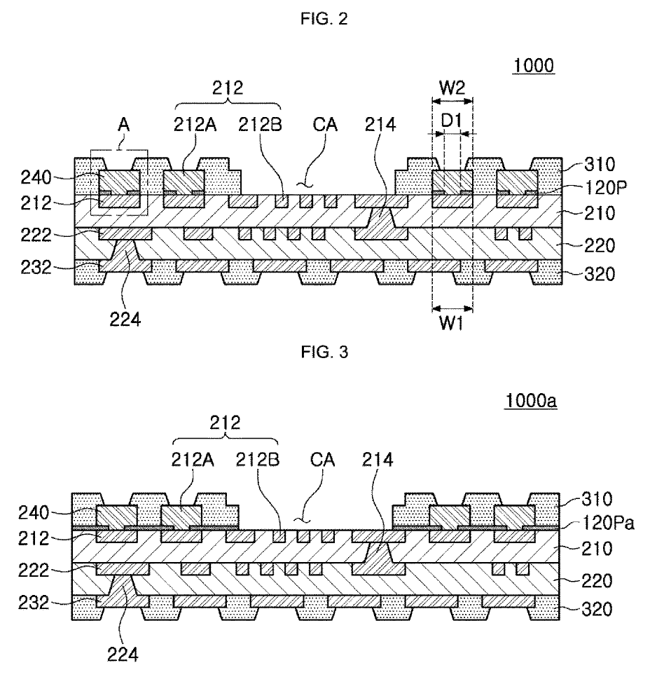

FIG. 2 and FIG. 3 are diagrams illustrating an example of a circuit board.

Referring to the example of FIG. 2, a circuit board 1000 according to the example of FIG. 2 includes first to third circuit layers 212, 222, 232, first and second insulating layers 210, 220 to cover the first and the second circuit layers 212, 222, a barrier layer 120P and a metal post 240 formed on a portion of the first circuit layer 212, and first and second solder resists 310, 320 located on the upper surface and the lower surface of the circuit board 1000, respectively. Also, in an example, the circuit board 1000 further includes a first via 214 configured to connect the first and the second circuit layers 212, 222 and a second via 224 configured to connect the second and the third circuit layers 222, 232. In such an example, the circuit board 1000 also has a structure that has a cavity CA at the center of its upper surface.

The first to the third circuit layers 212, 222, 232 function as circuit patterns in the circuit board 1000 and are formed of a conductive metal. In the example of FIG. 2, the first circuit layer 212 includes first circuit patterns 212A on which a metal post 240 is to be formed and second circuit patterns 212B on which the metal post 240 is not to be formed and of which at least a part is exposed through the cavity CA.

The first to the third circuit layers 212, 222, 232 are formed of, for example, Cu, Al, Ag, Sn, Au, Ni, Pd, or an alloy of such metals. However, these are only examples, and other metals with similar properties or other appropriate alloys are used in other examples. The first to the third circuit layers 212, 222, 232 also potentially function as a bump or an electrode when an electronic component is installed and/or mounted in addition to the circuit pattern.

The circuit board 1000 according to this example only has 3 circuit layers of the first to the third circuit layers 212, 222, 232 but the circuit board 1000 is not limited to using three layers. For example, the circuit board optionally includes two circuit layers or optionally further includes additional build-up layer(s).

For example, the first and the second vias 214, 224 are formed to connect between the first and the second circuit layers 212, 222 and between the second and the third circuit layers 222, 232, through the first and the second insulating layers 210, 220, respectively. The first to the third circuit layers 212, 222, 232, are formed on different layers from each other. Thus, in this example, the first to the third circuit layers 212, 222, 232 are electrically connected to form an electric path in the circuit board 1000. For example, such an electric path is electrically connected with electronic component(s) to be mounted and/or installed onto the circuit board 1000. In this example, the first and the second vias 214, 224 are formed of the same material used to form the first to the third circuit layers 212, 222, 232. For example, the first and the second vias 214, 224 are formed of CU, Al, Ag, Sn, Au, Ni, Pd, or an alloy thereof, or another appropriate material, as discussed above.

In the example of FIG. 2, the first and the second vias 214, 224 are independently formed as shown in FIG. 2 but the structure is not necessarily limited thereto. For example, in another example, the first and the second vias 214, 224 are formed in a staggered-via shape such that they are formed alternately with each other while connecting the layers or in a stacked-via shape that is laminated vertically.

It is illustrated in the example of FIG. 2 that the first and the second vias 214, 224 are filled completely with a conductive metal. However, a filling technique for the first and the second vias 214, 224 is not necessarily limited thereto. For example, the conductive metal is potentially filled only along the side wall of the via holes. It is also illustrated in the example of FIG. 2 that the first and the second vias 214, 224 are formed in a tapered shape with an increasing cross-sectional dimension toward the lower surface. However, the first and the second vias 214, 224 are optionally formed, in another example, to have a tapered shape with a decreasing cross-sectional dimension toward the lower surface, or to have a cylindrical shape.

In an example, the first and the second insulating layers 210, 220 are each a resin insulating layer. For example, such a resin insulating layer is formed of a thermosetting resin such as an epoxy resin, a thermoplastic resin such as a photo-reactive resin and a polyimide, or a resin in which a reinforcing agent such as glass fiber or an inorganic filler is implemented therein such as a prepreg. However, these are only examples of possibly resin insulating layers and other appropriate materials are optionally used as alternatives in other examples. Also, in examples, the first and the second insulating layers 210, 220 are formed of the same material or different materials.

In the example of FIG. 2, the metal post 240 is formed on the first circuit pattern 212A that is formed at the outside of the cavity CA. In this example, the metal post 240 is formed of a conductive material, for example, Cu. However, other appropriate conductive materials are optionally used in other examples.

Here, the barrier layer 120P is formed to prevent access of the second circuit pattern 212B that is exposed through the cavity CA when the metal post 240 is formed and the following process is performed. The barrier layer 120P is formed on a portion of the interface of the first circuit layer 212 and the metal post 240. For example, the barrier layer 120P is formed along the circumference of the metal post 240 on the lower part of the metal post 240 and the metal post 240 is connected with the first circuit layer 212A at its center.

In an example, the barrier layer 120P includes an organic material such as a thermosetting resin or a photo-reactive resin. A thermosetting resin is a petrochemical that cures in response to heat, while a photo-reactive resin is a resin that cures in response to light. For example, the barrier layer 120P is a primer resin layer, where a primer resin is a preparatory coating. However, the barrier layer 120P is not limited to a primer resin. For example, the barrier layer 120P is formed of a photosensitive material that acts a barrier, and hardens in response to light.

For example, the metal post 240 has a second width W2 that is equal or similar to a first width W1 of the first circuit pattern 212A that is formed on the lower part of the metal post 240. However, the first and the second widths W1, W2 are not limited to these size constraints and other appropriate size relationships are present in other examples. Also, the barrier layer 120P exposes a portion D1 of the first circuit pattern 212A in which the size of the portion D1 varies within a range that is less than the first width W1.

The first solder resist 310 is formed to expose the metal post 240 on the top surface of the circuit board 1000 so as to define the cavity CA. The first solder resist 310 is thus formed to expose the upper surface of the second circuit pattern 212B inside the cavity CA and to cover the edge part of the circuit board 1000. The second solder resist 320 is formed to expose the third circuit layer 232 on the lower surface of the circuit board 1000.

In this example, the first and the second solder resists 310, 320 are formed of a photosensitive resin, having properties as discussed above.

The circuit board 1000 prevents recessing of the second circuit pattern 212B of the first circuit layer 212, which is exposed through the cavity CA, using the barrier layer 120P during the manufacturing process and further allows thinner sizing by being formed to have a coreless structure.

Referring to the example of FIG. 3, a circuit board 1000a according to an example includes first to third circuit layers 212, 222, 232, first and second insulating layers 210, 220 formed to bury the first and the second circuit layers 212, 222, a barrier layer 120Pa. The circuit board 1000a also includes a metal post 240 that is formed on a part of the first circuit layer 212, and first and second solder resists 310, 320 formed on the upper surface and the lower surface of the circuit board 1000a, respectively.

In the example of FIG. 3, the barrier layer 120Pa is extended from the interface of first circuit patterns 212A of the first circuit layer 212 and the metal post 240 to the lower part of the first solder resist 310. For example, the barrier layer 120Pa is formed on the lower part of the metal post 240, except for the center part.

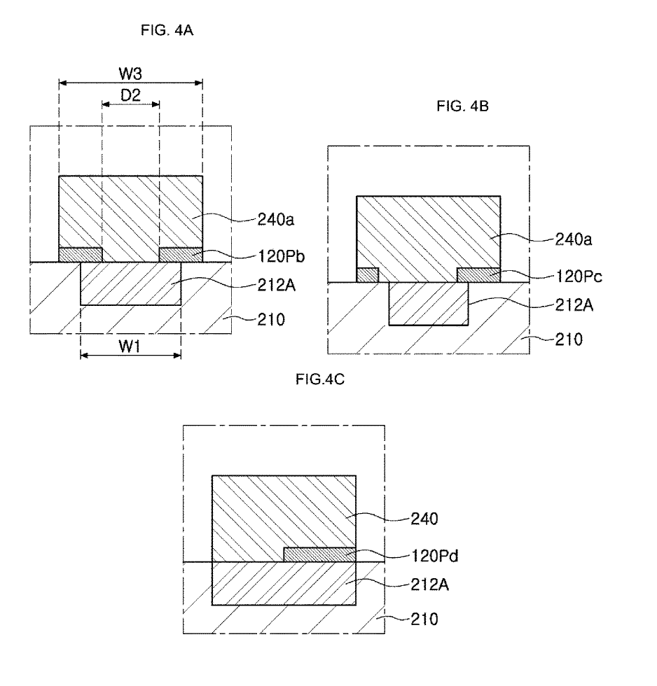

FIGS. 4A to 4C are diagrams illustrating portions of an example of a circuit board. More specifically, FIGS. 4A to 4C are diagrams illustrating the enlarged ‘A’ portion of the example of FIG. 2.

FIG. 4A illustrates the first circuit pattern 212A, the metal post 240a and the barrier layer 120Pb formed at the interface of the first circuit pattern. In an example, a width W3 of the metal post 240a is greater than the first width W1 of the first circuit pattern 212A.

For example, the barrier layer 120Pb is extended to have a predetermined length starting from the interface of first circuit patterns 212A and the metal post 240 and extending to the interface of the metal post 240a and the first insulating layer 210.

In this example, the barrier layer 120Pb exposes a portion D2 of the first circuit pattern 212A in which the portion D2 has the same or different features from the portion D1 in the circuit board 1000.

FIG. 4B illustrates the first circuit pattern 212A, the metal post 240a and the barrier layer 120Pc that is formed at the interface between the first circuit pattern 212A and the metal post 240a. In the example of FIG. 4B, the barrier layer 120Pc is formed to extend from the interface of the metal post 240a and the first circuit pattern 212A to the interface of the metal post 240a and the first insulating layer 210 on one side of these elements, such as the right side, and is possibly alternatively only formed at the interface of the metal post 240a and the first insulating layer 210 on the other side such as the left side. For example, the barrier layer 120Pc is formed asymmetrically in at least one direction.

FIG. 4C illustrates the first circuit pattern 212A, the metal post 240 and the barrier layer 120Pd formed at the interface of the first circuit pattern 212A and the metal post 240. In the example of FIG. 4C, the barrier layer 120Pd is formed only on the interface of the metal post 240 and the first circuit pattern 212A only on one side of the lower part of the metal post 240. For example, the barrier layer 120Pd is formed asymmetrically in at least one direction.

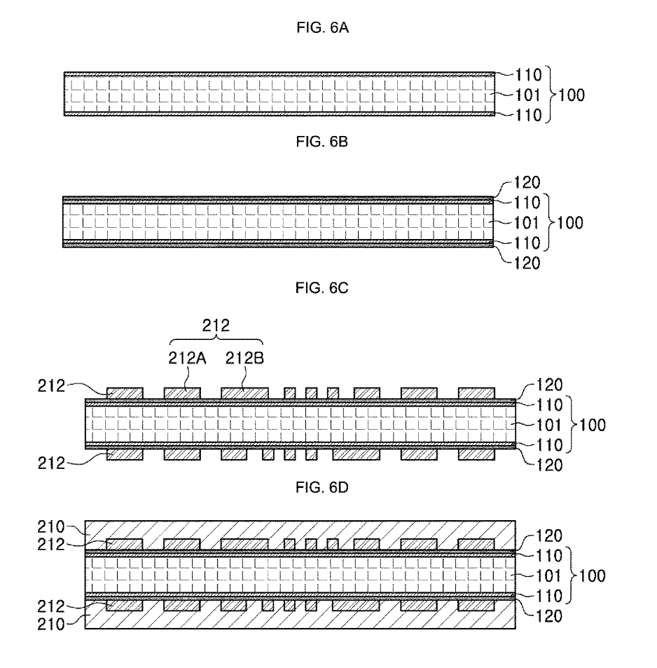

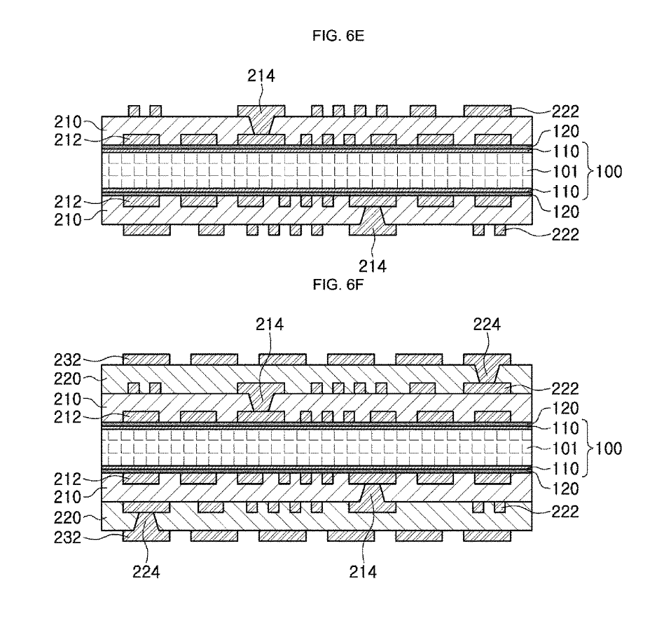

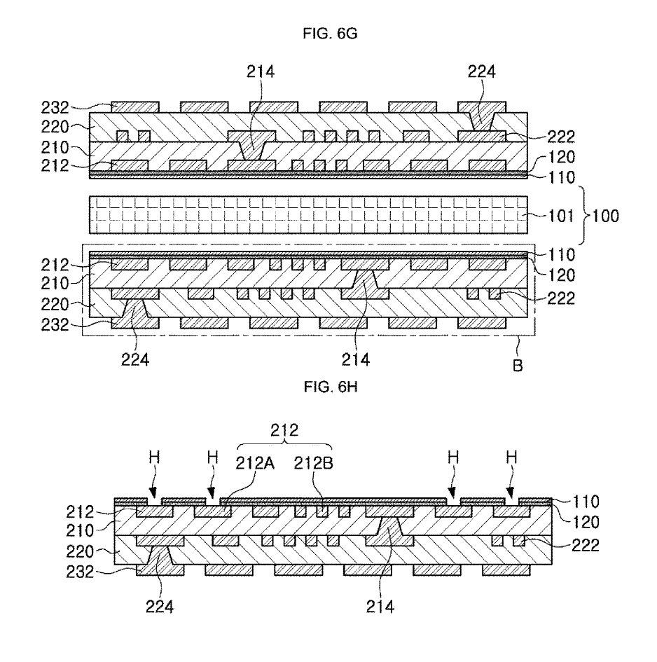

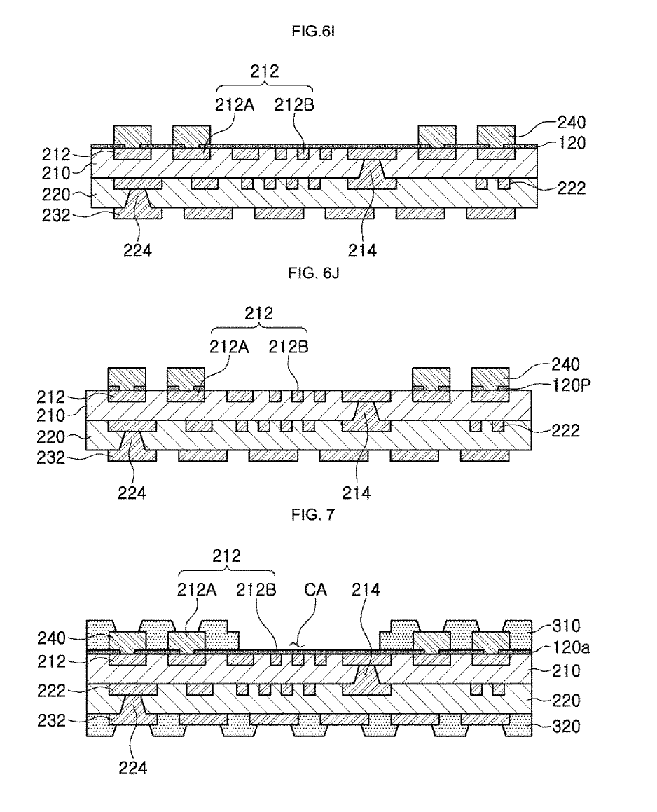

Accordingly, the barrier layers 120Pb, 120Pc, 120Pd of FIG. 4A to FIG. 4C are formed in various shapes depending on manufacturing conditions when opening parts H are formed. For example, FIG. 6H, below, further explains positions of the opening parts H and/or other appropriate other parts are formed.

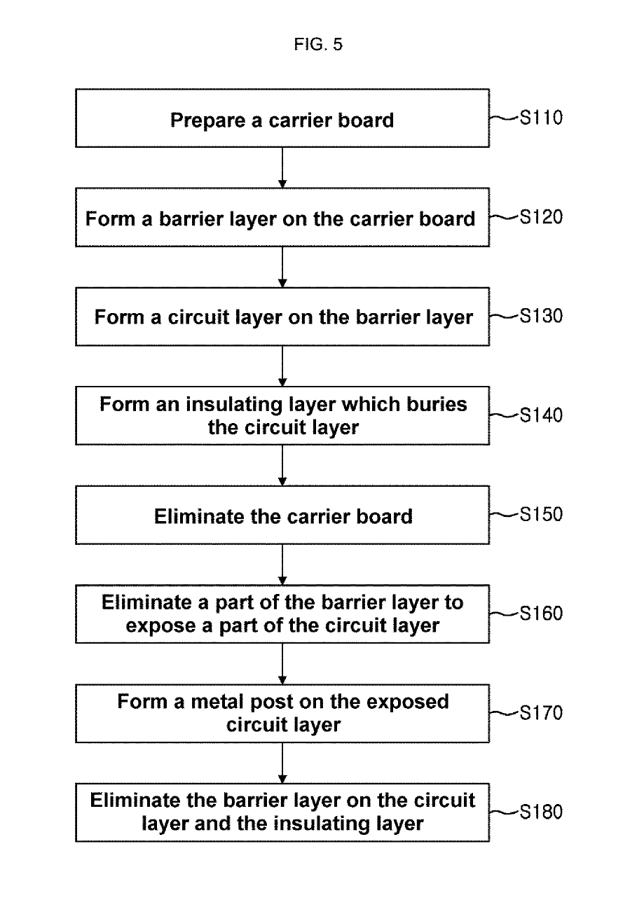

FIG. 5 is a flowchart illustrating an example of a method for manufacturing a circuit board.

FIG. 6A to FIG. 6J are diagrams illustrating steps of an example of a method for manufacturing a circuit board.

In S110, referring to the examples of FIG. 5 and FIG. 6A, a carrier board 100 is prepared.

For example, the carrier board 100 includes an insulating plate 101 and a metal layer 110 formed on both surfaces of the insulating plate 101. Such metal layers 110 potentially include an inner-layer metal foil and an outer-layer metal foil that is formed on the inner-layer metal foil. In an example, the inner and the outer-layer metal foils are Cu foils but are not to be limited thereto. In an example, at least one joint surface of the inner-layer and the outer-layer metal foils is surface-treated to facilitate the separation from the carrier board 100. In an example, a release layer is also formed between the inner-layer and the outer-layer metal foils to facilitate the separation from the carrier board 100.

In S120, with reference to FIG. 5 and FIG. 6B, a barrier layer 120 is formed on both surfaces of the carrier board 100.

For example, the barrier layer 120 is formed by performing coating with a primer resin. However, a relative thickness of the barrier layer 120 is not to be limited to the thickness shown in FIG. 6B, and other examples include other appropriate thicknesses. Also, the barrier layer 120 is not formed on both surfaces of the carrier board 100 but is possibly formed on only one surface.

In S130, referring to the examples of FIG. 5 and FIG. 6C, a first circuit layer 212 is formed on the barrier layers 120.

For example, the first circuit layer 212 includes a first circuit pattern 212A on which a metal post 240 is to be formed and a second circuit pattern 212B on which the metal post 240 is not to be formed.

In examples, the first circuit layer 212 is formed using a dry film pattern by a chemical vapor deposition (CVD) technique, a physical vapor deposition (PVD) technique such as sputtering, a subtractive process, an additive process using electroless copper plating or copper electroplating, a semi-additive process (SAP) and a modified semi-additive process (MSAP).

In S140, referring to the examples of FIG. 5 and FIG. 6D, a first insulating layer 210 is formed to cover the first circuit layer 212.

For example, the first insulating layer 210 is formed by compressing an insulating resin in an unhardened film type using a laminator and then hardening the result. The first insulating layer 210 is also possibly formed by performing coating with an insulating material for forming a build-up layer and then hardening the result.

Referring to the example of FIG. 6E, a first via 214 is formed so as to pass through the first insulating layer 210, and a second circuit layer 222 is formed on the first insulating layer 210. Also, a via hole optionally formed using a mechanical drill and/or a laser drill in a portion where the first via 214 is to be formed. Here, in an example, the laser drill is a CO₂ laser or a YAG laser. However, the laser drill is not to be limited to these examples, and other appropriate drills are used in other examples.

In this example, the second circuit layer 222 is formed by using the same method used for forming the first circuit layer 212. Also, in this example, when the first circuit layer 212 is formed, the first via 214 is formed by filling the via hole with a conductive material.

Referring to the example of FIG. 6F, a second insulating layer 220 is formed to cover the second circuit layer 222. For example, a second via 224 is formed to pass through the second insulating layer 220 and a third circuit layer 232 is formed on the second insulating layer 220.

Accordingly, the second insulating layer 220 is formed by using the same method used for forming the first insulating layer 210.

Likewise, the second via 224 and the third circuit layer 232 are formed by using the same method used for forming the first via 214 and the second circuit layer 222, as shown in FIG. 6E.

The number of such build-up layers, such as the second insulating layer 220 and the third circuit layer 232, varies with operational goals and demands. In another example, only one build-up layer is formed.

In S150, referring to the examples of FIG. 5 and FIG. 6G, a part of the metal layer 110 is separated, such as by using a blade to eliminate at least a part of the carrier board 100 by making an appropriate incision.

In this example, the carrier board 100 is separated using a blade. However, the separation method is not limited use of a blade. For example, the separation of the carrier board 100 is potentially separation of the inner-layer metal foil from the outer-layer metal foil of the metal layer 110. It is illustrated in the example FIG. 6E that the metal layer 110 is remained on the circuit board separated from the lower part of the carrier board 100. However, other examples are not limited to this particular example. For example, the separation is between the metal layer 110 and the barrier layer 120.

Subsequently, the circuit board B that is separated from the lower part of the carrier board 100 is used to explain the following steps.

In S160, referring to the examples of FIG. 5 and FIG. 6H, opening parts H are formed so as to expose a part of the first circuit pattern 212A of the first circuit layer 212 by eliminating the barrier layer 120 and the upper metal layer 110.

The barrier layer 120 and the upper metal layer 110 are eliminated to expose a part of the first circuit pattern 212A. For example, the exposed part is the center part, where the metal post 240 is to be formed.

For example, the opening parts H are formed using a mechanical drill and/or a laser drill. Here, the laser drill may be a CO₂ laser or a YAG laser. However, the laser drill is not limited to such lasers, as discussed previously. The opening parts H are also possibly formed using an etching process such as a dry etching process.

In S170, referring to the examples of FIG. 5 and FIG. 6I, a metal post 240 is formed on the exposed first circuit layer 212.

Thus, the metal post 240 is formed using electroplating after forming a mask layer which exposes the portion, where the metal post 240 is to be formed. For example, the mask layer uses a resist layer such as a dry film. The metal post 240 is also potentially formed by using the metal layer 110 as a seed layer or after forming an additional seed layer. In this example, after the metal post 240 is formed, the seed layer is eliminated.

When the metal layer 110 and/or the seed layer is or are eliminated, because the second circuit pattern 212B, on which the metal post 240 is not formed, is protected by the barrier layer 120, recess problems are avoided.

In S180, referring to the examples of FIG. 5 and FIG. 6J, the exposed barrier layer 120 on the first circuit layer 212 and the first insulating layer 210, where the metal post 240 is not formed, are eliminated.

For example, the barrier layer 120 is eliminated through an etching process, such as a wet etching process, without any mask. The barrier layer 120P thus remains at the interface between the metal post 240 and the first circuit pattern 212A on the lower part of the metal post 240.

The reference number of the remaining barrier layer 120P is used differently from that of the barrier layer 120 only to distinguish these barrier layers from one from another.

However, before the first and the second solder resists 310, 320 are formed, a surface treatment process is possibly further performed to form roughness on the surface to improve the adhesion of the surface to the first and the second solder resists 310, 320. For example, the surface treatment process is optionally performed before eliminating the barrier layer 120. The second circuit pattern 212B, on which the metal post 240 is not formed, is also potentially protected so as not to cause formation of a recess by the barrier layer 120.

For example, as part of this process, a first solder resist 310, which defines a cavity CA and exposes the metal post 240 on the top, and a second solder resist 320, which exposes the third circuit layer 232 at the bottom, are formed.

FIG. 7 is a diagram illustrating a part of a method for manufacturing a circuit board according to an example.

The above-described method is performed with reference to FIG. 6A to FIG. 6I. Referring to the example of FIG. 7, the first and the second solder resists 310, 320 are formed.

In this example, the first and the second solder resists 310, 320 are formed before the exposed barrier layer 120a is eliminated. The barrier layer 120a thus extends from the interface of the first circuit layer 212 and the metal post 240 to the lower part of the first solder resist 310.

Referring to the example of FIG. 7, the barrier layer 120a that is exposed through the cavity CA is eliminated to form the circuit board 1000a of FIG. 3.

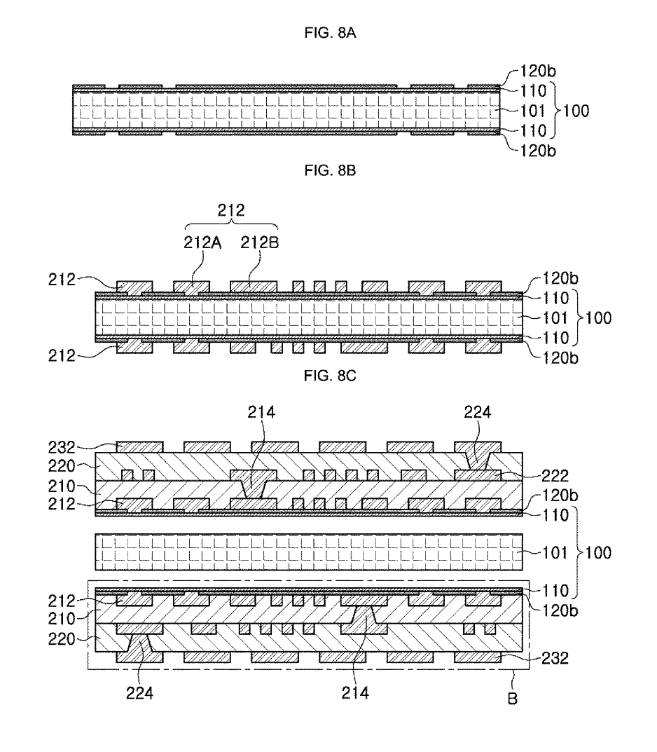

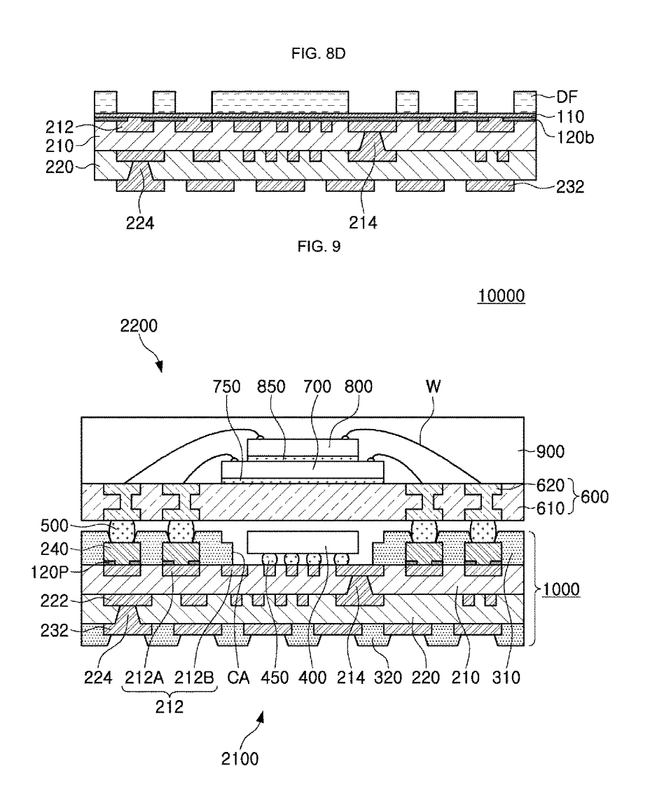

FIG. 8A to FIG. 8D are diagrams illustrating steps of an example of a method for manufacturing a circuit board according to an example. In FIG. 8A to FIG. 8D, any description that overlaps with FIG. 6A to FIG. 6J is omitted for brevity.

Referring to the example of FIG. 8A, a barrier layer 120b is formed by performing patterning on both surfaces of the carrier board 100.

In this example, the barrier layer 120b possibly formed of a photo imageable dielectric (PID) but the material is not to be limited to this example and other appropriate alternative materials are used in other examples. Here, the patterning is performed using a photolithography process instead of a laser process.

Referring to the example of FIG. 8B, a first circuit layer 212 is formed on the barrier layer 120b.

The first circuit layer 212 is potentially formed using various methods including the method described above with reference to the example of FIG. 6C. For example, a first circuit pattern 212A is formed on the exposed carrier board 100 where the metal post 240 is to be formed, as shown in FIG. 2.

Referring to the example of FIG. 8C, after forming build-up layers on the both surfaces of the carrier board 100, at least a part of the metal layer 110 is separated to eliminate at least a part of the carrier board 100.

As described above with reference to the examples of FIG. 6D to FIG. 6F, second and third circuit layers 222, 232, first and second vias 214, 224 and second insulating layer 220 are formed accordingly.

Furthermore, as described above with reference to the example of FIG. 6G, the carrier board 100 is separated using a blade.

Referring to the example of FIG. 8D, a mask layer DF is formed so as to form the metal post 240 on the barrier layer 120b in the one separated circuit board.

In this example, the mask layer DF is a resist layer such as a dry film and is patterned to expose the portion where the metal post 240 is to be formed.

As described above with reference to the example of FIG. 6I, the metal post 240 is formed using electroplating. In this case, the metal post 240 is also optionally formed by using the metal layer 110 as a seed layer or after forming additional seed layer. After the metal post 240 is formed, the seed layer is eliminated.

When the metal layer 110 and/or the seed layer is or are eliminated, because the second circuit pattern 212B, on which the metal post 240 is not formed, is protected by the barrier layer 120b, formation of a recess is avoided.

As described above with reference to the example of FIG. 6J, elimination of the exposed barrier layer 120b and formation of first and second solder resists 310, 320 is performed. The circuit boards 1000, 1000a are manufactured as shown in the example of FIG. 2 or FIG. 3, respectively.

FIG. 9 is a diagram illustrating an example of a semiconductor package including a circuit board.

Referring to the example of FIG. 9, a semiconductor package 10000 according to an example potentially includes a first package 2100 and a second package 2200. For example, the semiconductor package 10000 is a package on package type in which the second package 2200 is laminated onto the first package 2100.

In this example, the first package 2100 includes a first circuit board 1000 and a first chip 400 mounted on a cavity C of the first circuit board 1000. For example, the first package 2100 further includes a bump 450 so as to electrically connect between the first circuit board 1000 and the first chip 400.

It is illustrated in the example of FIG. 9 that the first circuit board 1000 is a circuit board that is the same circuit board as that of FIG. 2. However, the first circuit board 1000 in the example of FIG. 9 is not limited to the circuit board of FIG. 2. For example, the first circuit board 1000 is optionally the circuit board shown in the examples of FIG. 3 to FIG. 4C.

For example, the first chip 400 includes at least one semiconductor chip. In this example, the first chip 400 is mounted to have a flip-chip type by forming an active layer. For example, the first chip 120 is a logic semiconductor chip or a memory semiconductor chip. In an example, the logic semiconductor chip is a microprocessor, for example a central processing unit, a controller for an application specific integrated circuit, or a similar microprocessor. In examples, the memory semiconductor chip is a volatile memory such as DRAM (dynamic random access memory), SRAM (static random access memory) or another appropriate type of volatile memory, or a non-volatile memory such as a flash memory or a similar appropriate type of non-volatile memory.

The bump 450 is formed on the second circuit patterns 212B of the first circuit layer 212 so as to electrically connect between the first circuit board 1000 and the first chip 400.

For example, the second circuit pattern 212B is not be recessed from the upper surface of the first circuit board 1000, though it is stably connected with the bump 450. For example, the bump 450 optionally includes at least one of Au, Ag, Pt, Al, Cu and solder as a connective material, but other appropriate connective materials are possible. For example, the bump 450 is formed through a sputtering process, a plating process such as plus plating and DC plating, a soldering process or an adhesion process. However, the material and the method for forming the bump 450 are not to be limited to these examples, and other appropriate alternatives are available. For example, various types of signal transmission media such as a wire or a solder ball are optionally used.

In the example of FIG. 9, the second package 2200 includes a second circuit board 600, second and third chips 700, 800 that are mounted on the second circuit board 600, and a sealing material 900. In this example, the second package 2200 further includes adhesion layers 750, 850 that are formed on the lower part of the second and third chips 700, 800 and a wire W that electrically connects between the second and third chips 700, 800 and the second circuit board 600.

Also, in an example, the second circuit board 600 includes a body part 610 and an electrode pattern 620. For example, the body part 610 is formed of a material such as a resin, a ceramic material or a metal and the electrode pattern 620 is a metal layer formed of Au, Ag, Pt, Al, or Cu. However, these are only examples of materials and other alternative materials may be used, as appropriate.

For example, the second and the third chips 700, 800 include at least one semiconductor chip. In an example, the second and the third chips 700, 800 include a logic semiconductor chip and/or a memory semiconductor chip. However, the number of chips mounted on the second circuit board 600 is not to be limited, and additional chips are optionally included in other examples.

The wire W is optionally a wire for bonding semiconductors that acts as a signal transmission medium, so as to electrically connect the second and the third chips 700, 800 and the second circuit board 600. Various types of signal transmission media such as a bump and a solder ball are also potentially used in addition to the wire in other examples.

For example, the sealing material 900 wraps and protects the second and the third chips 700, 800 and the wire W. In an example, the sealing material 900 is a silicon-based material, a thermosetting material, a thermoplastic material, a UV treatment material or the like. As another example, the sealing material 900 may be formed of a polymer such as a resin, for example, an epoxy molding compound. However, these are only examples and other materials are optionally used as the sealing material 900.

In this example, the first package 2100 and the second package 2200 are electrically connected through the solder ball 500 with each other. For example, the solder ball 500 is formed between the metal post 240 of the first circuit board 1000 and the electrode pattern 620 of the second circuit board 600 to connect the metal post 240 and the electrode pattern 620. In one example, the solder ball 500 is formed of a solder material, but other examples use other materials. For example, the solder ball 500 optionally includes at least one of Sn, Ag, Cu and Al in its composition. Also, the solder ball 500 is optionally formed in various shapes including the shape in FIG. 9.

The total thickness of the semiconductor package 10000 according to an example is thus minimized by using the lower first circuit board 1000 in which the cavity CA is formed, while including a plurality of semiconductor chips such as the first to the third chips 400, 700, 800, as discussed above.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation,

Expressions such as “first conductivity type” and “second conductivity type” as used herein may refer to opposite conductivity types such as N and P conductivity types, and examples described herein using such expressions encompass complementary examples as well. For example, an example in which a first conductivity type is N and a second conductivity type is P encompasses an example in which the first conductivity type is P and the second conductivity type is N.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A circuit board comprising:
an insulating layer;
a first circuit layer that is buried in one surface of the insulating layer;
a metal post located on the first circuit layer; and
a barrier layer located on a portion of an interface between the first circuit layer and the metal post.

2. The circuit board of claim 1, wherein the barrier layer is located along a circumference of the metal post on a lower part of the metal post and the metal post is connected to the first circuit layer at a center of the metal post.

3. The circuit board of claim 1, further comprising a solder resist located to expose a part of the first circuit layer and the metal post.

4. The circuit board of claim 3, wherein the barrier layer extends onto a lower part of the solder resist.

5. The circuit board of claim 3, wherein the metal post and the solder resist are arranged at an edge of the circuit board so to define a cavity at a center of the circuit board.

6. The circuit board of claim 1, wherein a width of the metal post is equal to or greater than a width of the first circuit layer.

7. The circuit board of claim 1, wherein the barrier layer is formed of an organic material.

8. The circuit board of claim 7, wherein the barrier layer is formed of a photosensitive material.

9. The circuit board of claim 1, wherein the circuit board has a coreless structure.

10. A circuit board comprising:
an insulating layer;
a first circuit layer that is buried in one surface of the insulating layer and comprises a first circuit pattern that is formed at a center of the first circuit layer and a second circuit pattern formed at an edge of the first circuit pattern;
a metal post formed on the second circuit pattern; and
a barrier layer formed on a portion of the interface between the second circuit pattern and the metal post.

11. A method for manufacturing a circuit board comprising:
preparing a carrier board;
forming a barrier layer on a surface of the carrier board;
forming a circuit layer on the barrier layer;
forming an insulating layer into which the circuit layer is buried;
eliminating at least a part of the carrier board;
eliminating at least a part of the barrier layer to expose a part of the circuit layer; and
forming a metal post on the exposed circuit layer.

12. The method of claim 11, wherein the metal post is formed to extend into the barrier layer and the barrier layer is thus formed on a portion of the interface between the metal post and the circuit layer.

13. The method of claim 11, wherein the at least a part of the barrier layer is eliminated using a laser.

14. The method of claim 11, further comprising eliminating the exposed barrier layer after the forming the metal post.

15. The method of claim 11, wherein the metal layer of the carrier board is made to remain on the barrier layer after the eliminating at least a part of the carrier board, and the metal post is eliminated during the eliminating the at least a part of the barrier layer.

16. The method of claim 11, wherein the barrier layer is formed of a photosensitive material.

17. The method of claim 11, further comprising patterning the barrier layer before the forming of the circuit layer.
